(19) United States
(12) Patent Application Publication
(10) Pub. No.: US 2012/0313671 A1
(43) Pub. Date: Dec. 13, 2012

(54) SIGNAL GENERATION DEVICE AND SIGNAL GENERATION METHOD

(75) Inventors: Hiroyasu Sano, Tokyo (JP); Koji Tomitsuka, Tokyo (JP)

(73) Assignee: Mitsubishi Electric Corporation, Tokyo (JP)

(21) Appl. No.: 13/574,069

(22) PCT Filed: Jan. 14, 2011
(86) PCT No.: PCT/JP2011/050543

§ 371 Date: Jul. 19, 2012

(30) Foreign Application Priority Data
Jan. 19, 2010 (JP) 2010-009070

(51) Int. Cl. H03B 1/04

(52) U.S. Cl. 327/113

(57) ABSTRACT

A signal generation device includes: filter banks that perform sampling frequency conversion with respect to an input signal of a predetermined sampling frequency, and generate a signal obtained after the sampling frequency conversion as an output signal; a control-signal generation unit that selects the filter banks to be used based on a sampling-frequency setting value indicating a sampling frequency of the output signal: and a switching unit selects the filter banks based on a result of selection by the control-signal generation unit.

### FIELD

The present invention relates to a signal generation device and a signal generation method that generate a signal whose sampling frequency has been converted based on a sampled input signal.

### BACKGROUND

In radio communications and the like, sampling frequency conversion is sometimes performed for converting a signal having been sampled at one sampling frequency, into a signal having been sampled at another sampling frequency. A conventional sampling-frequency conversion method is explained below. A case of performing sampling frequency conversion by using an oversampling polyphase filter is explained here.

The oversampling polyphase filter is a filter used for generating a signal whose sampling frequency has been increased M times, and in order to form a filter H having desired filter characteristics, M filter banks for which a tap coefficient is respectively set are used. By selecting a signal output from each filter bank periodically at an equal time interval and providing the selected signal as an output signal, a filtering process and the sampling frequency conversion can be performed.

For example, when M is 4, an input signal sampled at a predetermined sampling interval is input to each of M (four) sub-filters. The tap coefficients of the four sub-filters are obtained by extracting the tap coefficients of the desired filter H at an equal interval so that an origin of extraction is shifted for each filter. When the four sub-filters are represented as F1 to F4 and sets of the tap coefficients of F1 to F4 are H₀={h(0,0), h(0,1), h(0,2), h(0,3), h(0,4)}, H1={h(1,0), h(1,1), h(1,2), h(1,3), h(1,4)}, H2={h(2,0), h(2,1), h(2,2), h(2,3), h(2,4)}, and H3={h(3,0), h(3,1), h(3,2), h(3,3), h(3,4)}, respectively, an impulse response of the filter H corresponding to 4-times oversampling becomes {h(0,0), h(1,0), h(2,0), h(3,0), h(0,1), h(1,1), . . . }. In this case, an FIR filter is assumed, and the tap coefficients of each filter bank are set based on the impulse response of the filter H corresponding to the 4-times oversampling.

As described above, by setting the tap coefficients of the filter banks corresponding to characteristics of the filter H and sequentially selecting the outputs from the four filter banks, which are F1, F2, F3, and F4, at an equal time interval within a sampling period of the input signal, it is possible to obtain an output signal whose sampling frequency has been converted into a four-times higher frequency.

### Citation List

### Non Patent Literature

Non Patent Literature 1: Nishimura, “Communication system design by digital signal processing”, CQ Publishing Co., Ltd., pp. 79-89 (June 2006)

### SUMMARY

### Technical Problem

However, according to the conventional sampling conversion method using a polyphase filter, there is a problem that, when an output signal is converted into an arbitrary sampling frequency, it is necessary to change the sampling frequency of an input signal as well as a frequency of an operation clock used for the sampling conversion.

Furthermore, to set the sampling frequency of the output signal to an arbitrary value when the operation clock frequency is fixed, it is necessary to use a plurality of polyphase filters for the oversampling and downsampling in combination. Therefore, there is a problem that the number of arithmetic operations is increased, and a memory size becomes large because the number of candidates of the tap coefficients of the polyphase filters is increased.

Further, in order to set the sampling frequency of the output signal to an arbitrary value when the operation clock frequency is fixed, it is necessary to use a plurality of filter banks corresponding to the sampling frequency of the output signal when the polyphase filters are constituted, and this causes a problem that the number of arithmetic operations is increased and a circuit size is enlarged.

The present invention has been achieved in view of the above problems, and an object of the present invention is to provide a signal generation device that can perform sampling frequency conversion at an arbitrary rate with a simple configuration, and a signal generation method.

### Solution to Problem

In order to solve the above problem and in order to attain the above object, a signal generation device of the present invention, includes: a filtering unit that performs sampling frequency conversion with respect to an input signal of a predetermined sampling frequency, and generates a signal obtained after the sampling frequency conversion as an output signal; and a control unit that selects, based on a sampling-frequency setting value indicating a sampling frequency of the output signal, a combination of tap coefficients used by the filtering unit from a plurality of combinations of tap coefficients determined in advance. Additionally, the filtering unit generates the sampling frequency conversion based on a result of selection by the control unit.

### Advantageous Effects of Invention

According to the signal generation device and the signal generation method of the present invention, a frequency of a high-speed operation clock is fixed, a filter bank unit is provided, a filter control unit selects sets of the tap coefficients to be set for the filter bank unit, based on a ratio between the frequency of the high-speed operation clock and a sampling frequency of an output signal, and the output obtained after the filter bank unit performs filtering using the selected sets of the tap coefficients is handled as an output signal obtained after sampling conversion, so that it is possible to perform sampling frequency conversion at an arbitrary rate with a simple configuration.

### BRIEF DESCRIPTION OF DRAWINGS

FIG. 1 is an example of a functional configuration of a signal generation device according to a first embodiment.

FIG. 2 is a configuration example of filter banks.

FIG. 3 is an example of a switching operation of a switching unit.

FIG. 4-1 is an example of tap coefficients corresponding to an impulse response of a desired filter characteristic H in 16-times oversampling.

FIG. 4-2 is an example of a set (H₀) of tap coefficients of a filter bank.

FIG. 4-3 is an example of a set (H₄) of tap coefficients of a filter bank.

FIG. 4-4 is an example of a set (H₈) of tap coefficients of a filter bank.

FIG. 4-5 is an example of a set (H₁₂) of tap coefficients of a filter banks.

FIG. 5 is a configuration example of a control-signal generation unit.

FIG. 6 is an example of an operation in a case where a ratio between a high-speed clock frequency and a sampling frequency of an output signal is four times.

FIG. 7 is an example of an operation in a case where a ratio between a high-speed operation clock frequency and a sampling frequency of an output signal is smaller than four times.

FIG. 8 is an example of an operation in a case where a ratio between a high-speed operation clock frequency and a sampling frequency of an output signal is two times.

FIG. 9 is an example of a functional configuration of a signal generation device according to a second embodiment.

FIG. 10 is an example of a functional configuration of a signal generation device according to a third embodiment.

FIG. 11 is an example of a configuration of an averaging processing unit.

### DESCRIPTION OF EMBODIMENTS

Exemplary embodiments of a signal generation device and a signal generation method according to the present invention will be explained below in detail with reference to the accompanying drawings. The present invention is not limited to the embodiments.

### First Embodiment

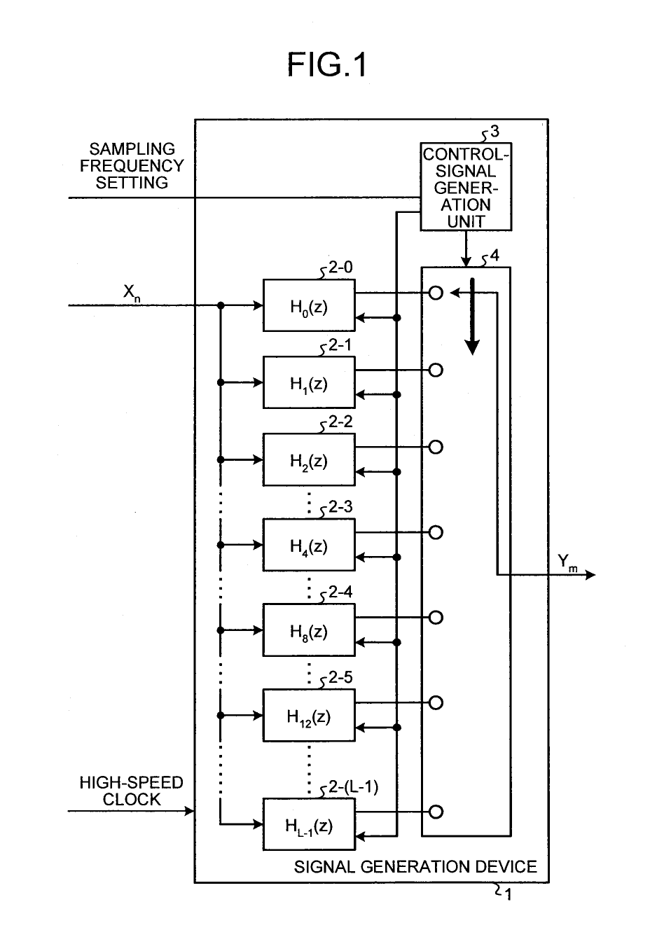

FIG. 1 is an example of a functional configuration of a signal generation device according to a first embodiment of the present invention. A signal generation device 1 according to the present embodiment performs a sampling-frequency conversion process on an input signal Xₙ (n indicates a sampling number) of a predetermined sampling frequency, and then outputs a signal Ym (m indicates a sample number given after the sampling-frequency conversion process) obtained after the sampling-frequency conversion process.

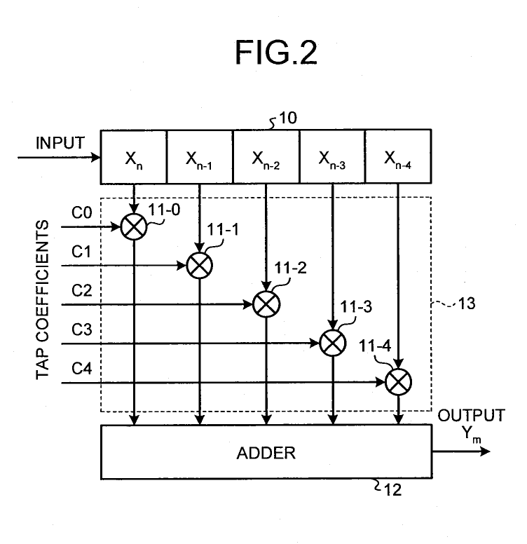

As shown in FIG. 1, the signal generation device 1 according to the present embodiment includes filter banks 2-0 to 2-(L-1) (L is an integer equal to or larger than 1), a control-signal generation unit (control unit) 3, and a switching unit 4. FIG. 2 is a configuration example of the filter banks 2-0 to 2-(L-1). While a case where the filter banks 2-0 to 2-(L-1) respectively use five tap coefficients is exemplified here, the number of the tap coefficients is not limited thereto. The filter banks 2-0 to 2-(L-1) have a configuration identical to each other, and are respectively constituted by a shift register 10, multipliers 11-0 to 11-4, and an adder 12. The multipliers 11-0 to 11-4 constitute a coefficient multiplication unit 13.

The configuration of the filter banks 2-0 to 2-(L-1) is identical to that of a general FIR (Finite Impulse Response) filter. The shift register 10 generates signals Xₙ, Xₙ₋₁, Xₙ₋₂, Xₙ₋₃, and Xₙ₋₄ that have been delayed from the input signal Xₙ by one sample relative to each other. The multiplier 11-0 multiplies Xₙ by a tap coefficient C0, the multiplier 11-1 multiplies Xₙ₋₁ by a tap coefficient C1, the multiplier 11-2 multiplies Xₙ₋₂ by a tap coefficient C2, the multiplier 11-3 multiplies Xₙ₋₃ by a tap coefficient C3, and the multiplier 11-4 multiplies Xₙ₋₄ by a tap coefficient C4. The adder 12 adds outputs from the multipliers 11-0 to 11-4 together, and then outputs them to the switching unit 4.

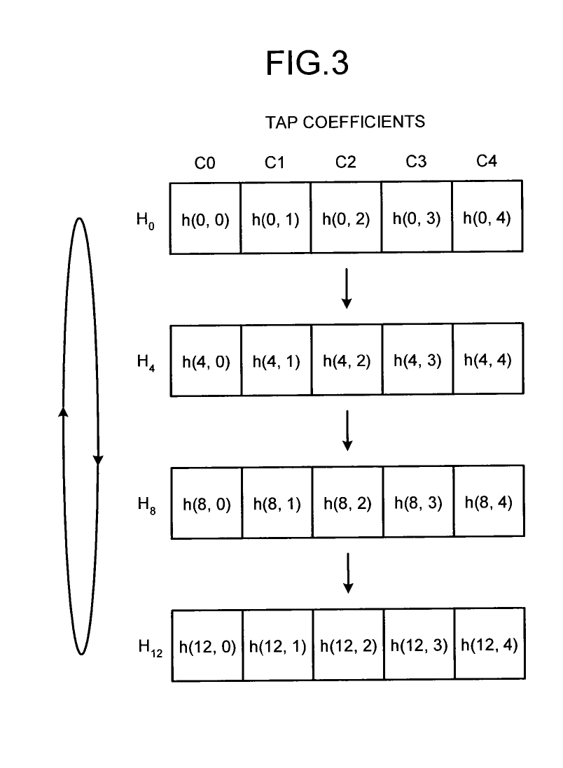

FIG. 3 is an example of a switching operation of the switching unit 4. FIGS. 4-1 to 4-5 are an example of tap coefficients of filter banks. The examples of the switching operation shown in FIG. 3 and FIGS. 4-1 to 4-5 represent a case where L is 16 (resolution of 16-times oversampling) and a case where a ratio between a high-speed operation clock frequency fclk and a sampling frequency fout of the output signal (fclk/fout) is 4.

Generally, in frequency conversion using a conventional polyphase filter, the operation clock frequency is the same as a sampling frequency of an output signal (a converted sampling frequency obtained after sampling frequency conversion), and by switching the filter banks based on the operation clock (switching among the filter banks to be selected as the output signal), the output signal of the converted sampling frequency can be generated.

On the other hand, in the present embodiment, the sampling frequency fout of a plurality of output signals is handled while the high-speed operation clock frequency fclk is fixed, and therefore fclk and fout are not necessarily the same. Accordingly, in the present embodiment, the filter banks to be selected are changed according to the ratio fclk/fout. In this example, L is 16, and the sampling frequency can be converted into a maximum frequency of 16 times with respect to the input signal Xₙ. Therefore, it suffices that the high-speed operation clock frequency fclk is higher than the sampling frequency 16 times as high as that of the input signal, and in this example, the high-speed clock frequency fclk is the sampling frequency 16 times as high as the input signal. In addition, in this example, the sampling frequency of the input signal Xₙ is fixed.

Based on the above assumption, when the ratio fclk/fout is 4, the sampling frequency four times as high as that of the input signal is obtained after conversion. Thus, four filter banks are used for the sampling frequency conversion. In this example, four of the filter banks 2-0, 2-4, 2-8, 2-12 (H₀, H4, H8, H12) are to be selected. For the filter banks 2-0 to 2-(L-1), it is assumed that sets of the tap coefficients H₀ to H_{L-1}, which are obtained by extracting the tap coefficients of a desired filter characteristic H that correspond to each filter bank, are set. In this example, because the number of taps is five, the number of the tap coefficients set for each filter bank is five (C0, C1, C2, C3, and C4).

Accordingly, the tap coefficients can be represented as H₀={h(0,0), h(0,1), h(0,2), h(0,3), h(0,4)}, H₁={h(1,0), h(1,1), h(1,2), h(1,3), h(1,4)}, H₂={h(2,0), h(2,1), h(2,2), h(2,3), h(2,4)}, . . . , H₄={h(4,0), h(4,1), h(4,2), h(4,3), h(4,4)}, . . . , H₁₅={h(15,0), h(15,1), h(15,2), h(15,3), h(15,4)}. Furthermore, H₀ to H_{L-1} are sets of tap coefficients that are extracted at an equal interval (an interval of L) from all the tap coefficients corresponding to the desired filter characteristic H so that an origin of the tap coefficients of each filter is shifted by one point from each other, and that are obtained by polyphase decomposition of the desired filter characteristic H.

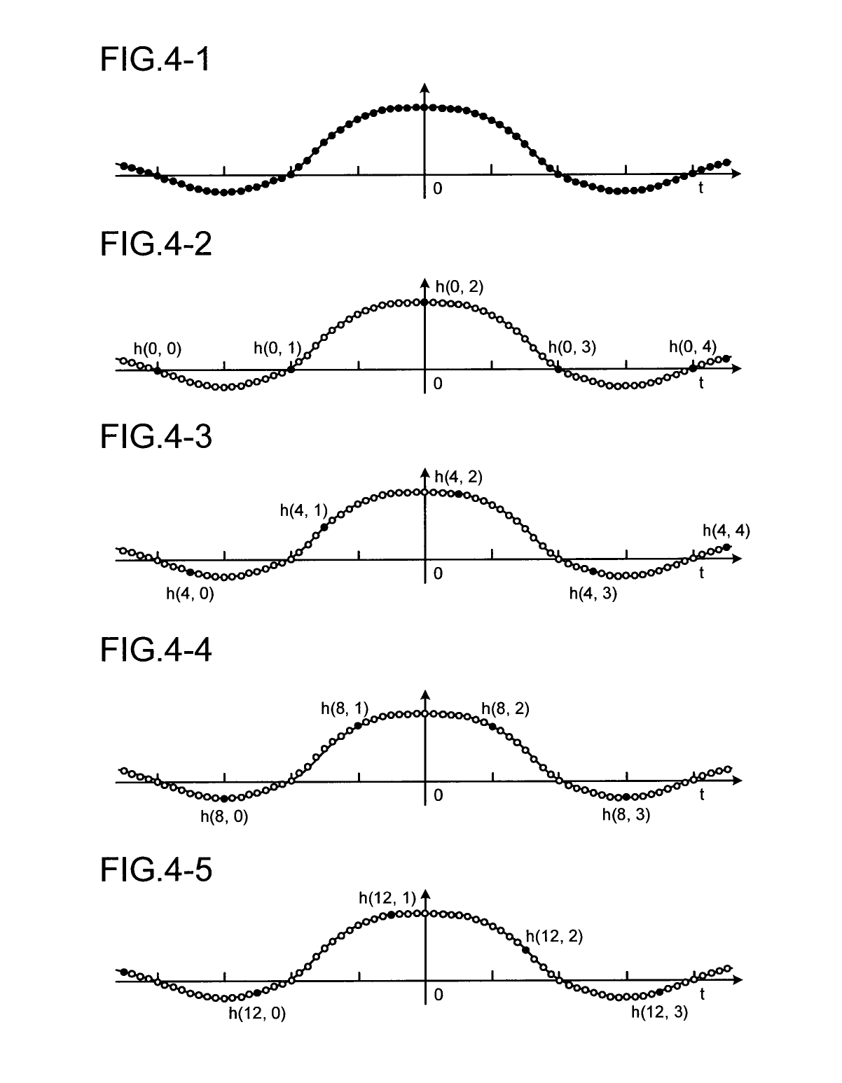

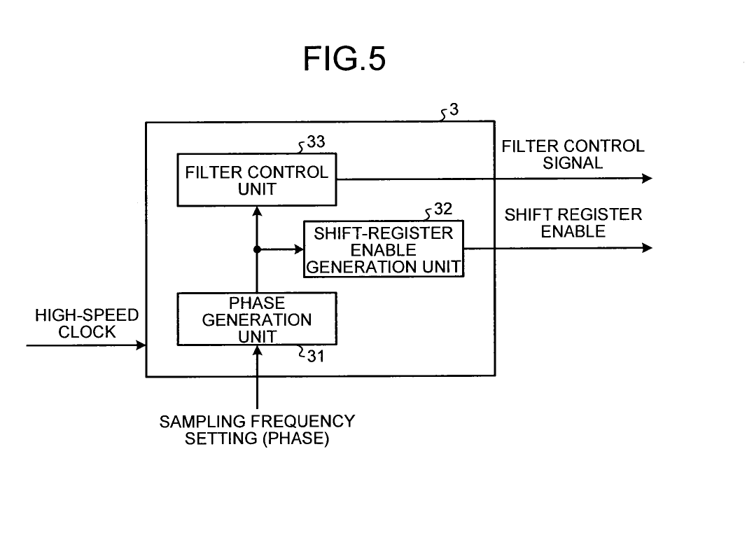

FIG. 3 depicts a switching operation among the selected four filter banks 2-0, 2-4, 2-8, and 2-12 (corresponding to H₀, H₄, H₈, and H₁₂, respectively) in sequence. FIG. 4-1 is an example of all the tap coefficients corresponding to an impulse response of the desired filter characteristic H in the 16-times oversampling, FIG. 4-2 depicts a set (H₀) of the tap coefficients of the filter bank 2-0, FIG. 4-3 depicts a set (H₄) of the tap coefficients of the filter bank 2-4, FIG. 4-4 depicts a set (H₈) of the tap coefficients of the filter bank 2-8, and FIG. 4-5 depicts a set (H₁₂) of the tap coefficients of the filter bank 2-12.

As shown in FIGS. 4-1 to 4-5, the tap coefficients of the filter banks 2-0, 2-4, 2-8, and 2-12 are those extracted from all the tap coefficients at an equal interval (an interval of L) so that the origin of the tap coefficients of each filter is shifted by four points from each other. Accordingly, as shown in FIG. 3, the switching unit 4 switches among the filter banks 2-0, 2-4, 2-8, and 2-12 at a time interval corresponding to fout, thereby generating the output signal Yₘ of the sampling frequency one-fourth fclk.

In the present embodiment, the sampling frequency fout of the output signal is set in the control-signal generation unit 3, the control-signal generation unit 3 generates a control signal transmitted to the switching unit 4 based on fout as described later, and the switching unit 4 switches among the filter banks to be selected based on the control signal. Processing of the control-signal generation unit 3 is explained below.

FIG. 5 is a configuration example of the control-signal generation unit 3. As shown in FIG. 5, the control-signal generation unit 3 is constituted by a phase generation unit 31, a shift-register enable generation unit 32, and a filter control unit 33.

The control-signal generation unit 3 operates on a high-speed operation clock (the frequency fclk). A sampling-frequency setting (phase), which is a value determined by a ratio between the high-speed clock frequency and an output sampling frequency, is input to the control-signal generation unit 3. It is assumed that the output sampling frequency is input to the control-signal generation unit 3, so that the control-signal generation unit 3 can calculate the sampling frequency setting (phase). A sampling frequency setting (phase) ΔP is a value obtained by a calculation of the following expression (1). Note that ΔP does not necessarily need to be an integer.

ΔP=L/(fclk/fout) (1)

In this example, the ratio fclk/fout is 4, and the sampling frequency setting (phase) ΔP becomes 4 accordingly.

In the present embodiment, a phase of 0 to 2π is expressed as a value having been converted into a linear value of 0 to (L-1), and ΔP is expressed as a converted phase. Based on the input sampling frequency setting (phase), the phase generation unit 31 integrates the phase and outputs as an output phase a result (0 to (L-1)) obtained by applying modulo-L arithmetic to the integral.

Specifically, the phase generation unit 31 determines an output phase P(k) from the following expression (2) based on ΔP, for example. Note that an initial value S(0) is 0.

S(k)=F{S(k−1)+ΔP}

P(k)=modulo{S(k), L} (2)

Reference sign F(·) denotes a function used for rounding off fractions, and k denotes a sample number of the output signal. Accordingly, it suffices to calculate P(k) once for every 4 (=fclk/fout) pulses of a high-speed clock. Note that F(·) can be a function for rounding down the fractions for simplicity of the arithmetic operation.

The phase generation unit 31 outputs the output phase P(k) to the shift-register enable generation unit 32 and the filter control unit 33. Based on the output phase P(k), the filter control unit 33 selects the filter bank 2-j determined from j=P(k) every time P(k) is updated (that is, once for 4 (=fclk/fout) periods of the high-speed clock), and outputs to the switching unit 4 a control signal for instructing to output the signal Y. (m is the sample number) having the filtering processing of the selected filter bank 2-j performed thereon. The switching unit 4 performs switching of filter banks based on this control signal.

Based on the output phase P(k), the shift-register enable generation unit 32 generates a shift-register enable pulse for instructing updating of contents in the shift register 10 of the filter banks 2-0 to 2-(L-1). Based on the shift-register enable pulse, the filter banks 2-0 to 2-(L-1) update a value of the shift register 10 to another value derived from the next (next sample) input signal. A method of generating the shift-register enable pulse of the shift-register enable generation unit 32 can be any method as long as it is for generating a shift-register enable pulse once for every sampling period of an input signal. As an example, it is assumed that the output phase P(k) is compared to a predetermined threshold a in the unit of high-speed clock cycles, and when P(k) becomes equal to or larger than a, a pulse is generated at every high-speed clock unit.

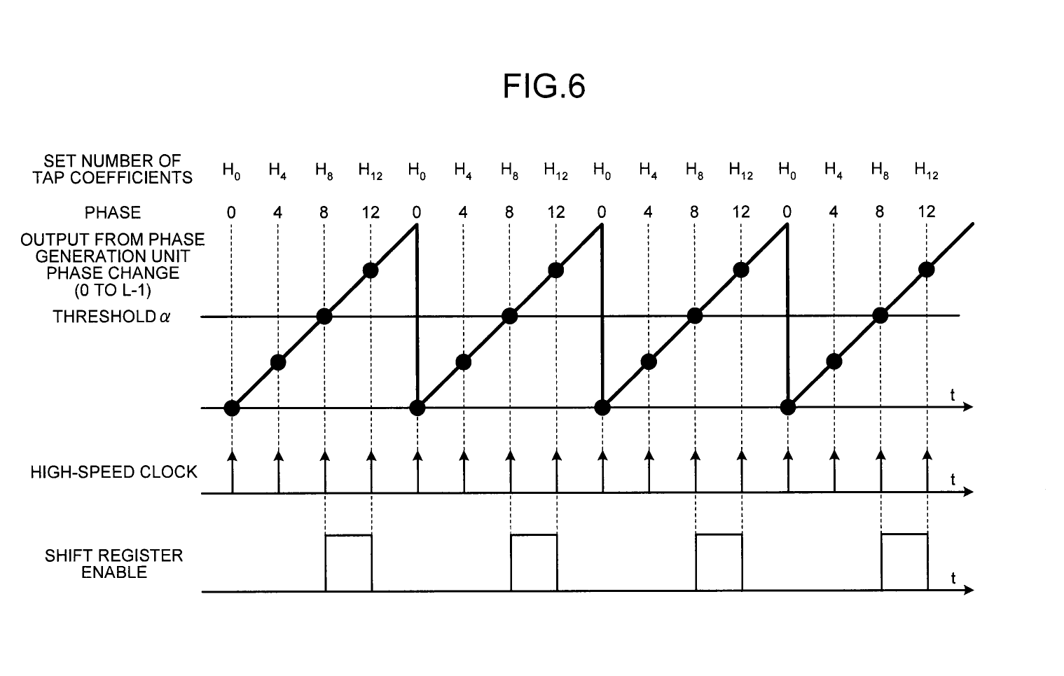

FIG. 6 is an example of an operation in a case where the ratio between the high-speed clock frequency and the sampling frequency of the output signal is four times. In FIG. 6, an arrow of the high-speed clock indicates one period out of four high-speed clock periods, and at the clock indicated by the arrow (once in four times), the filter banks 2-0 to 2-(L-1) are selected, and then the output signal from the selected filter banks 2-0 to 2-(L-1) is output as an output signal obtained after the sampling conversion. FIG. 6 depicts set numbers (H₀, H₄, H₈, and H₁₂) of the tap coefficients of the selected filter banks 2-j and the output phase at the specific time (the phase in FIG. 6).

Furthermore, a is L/2=8 in FIG. 6, and when P(k) becomes 8, the shift-register enable pulse is changed from Low to High. In FIG. 6, the shift-register enable pulse continues between the arrows (four units of the high-speed clock); however, in practice, it suffices to bring the shift-register enable pulse into High at one high-speed clock unit. Further, the value of a is not limited to 8, and can be any value between 0 to L-1.

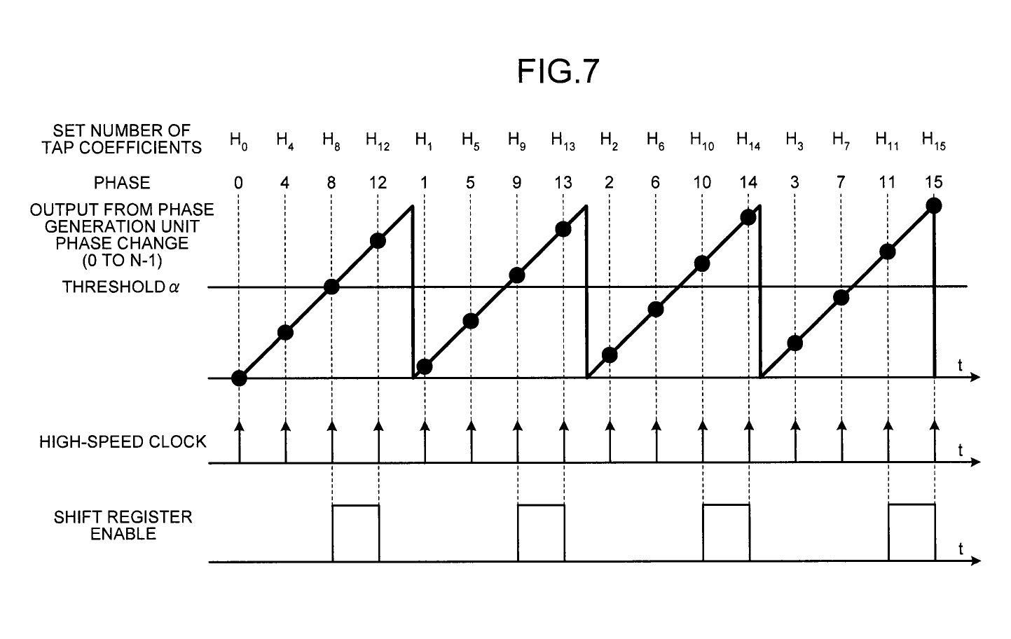

FIG. 7 is an example of an operation in a case where the ratio between the high-speed operation clock frequency and the sampling frequency of the output signal is smaller than four times. FIG. 7 is an operation example in a case where L is 16, the ratio fclk/fout between the high-speed operation clock frequency and the sampling frequency of the output signal is slightly smaller than 4, and ΔP is 4+b, which is slightly larger than 4 (for example, 0.5/4≦b<0.5/3).

In the case of the example in FIG. 7, the output phase P(k) calculated by the expression (2) is the same as that in the example in FIG. 6 on the first four points because the fractions of S(k) are rounded off. For example, S(0) is 0 (initial value) on the first point, S(3) is 3×ΔP=3×(4+b) on the fourth point, and thus P(3) is 12. Meanwhile, on the fifth point, 16 is obtained by rounding off S(4), which is 4×ΔP=4×(4+b). Therefore, P(4)=1 is established, and this means j=1 on the fifth point and thus the filter bank 2-1 (the set number H₁ of the tap coefficients) is selected. In this manner, the filter banks to be selected are subsequently changed, such as the filter banks 2-5, 2-9, 2-13, 2-2, 2-6, . . . , for every sampling period of the input signal.

As described above, in the present embodiment, S(k) is set to be an integer (by rounding off or rounding down the number), and then the filter bank to be selected is determined, thereby handling a case where the ratio between the high-speed operation clock frequency and the sampling frequency of the output signal is not an integral multiple. Therefore, even with a limited number of filter banks, it is possible to correspond to the sampling frequency of any output signal with a small error.

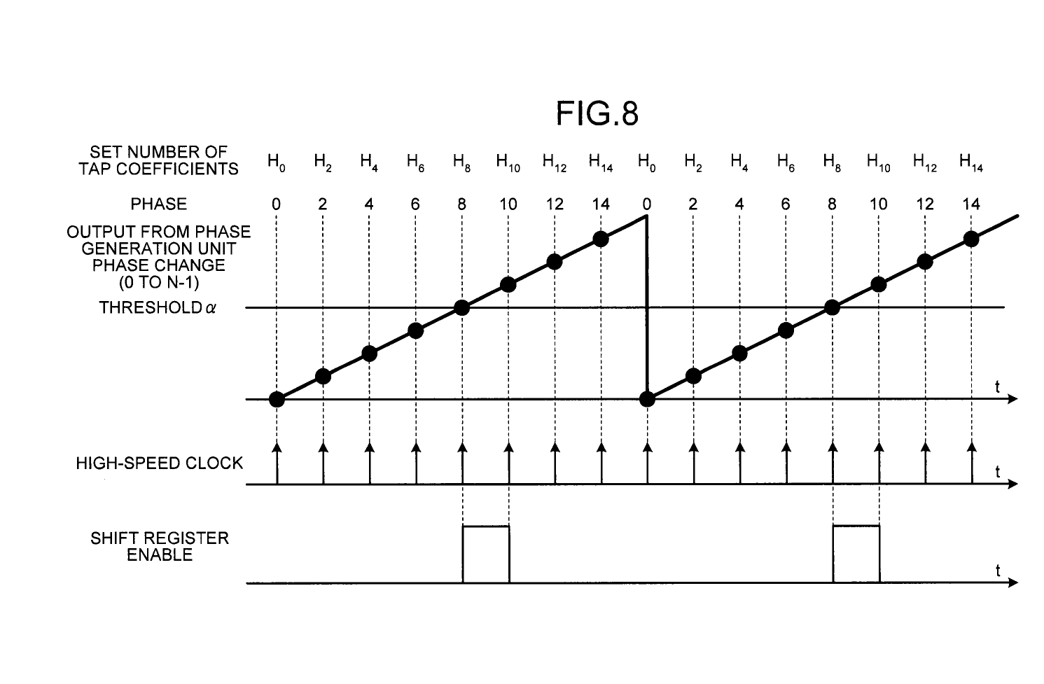

FIG. 8 is an example of an operation in a case where the ratio between the high-speed operation clock frequency and the sampling frequency of the output signal is eight times. In FIG. 8, because L is 16 and the ratio fclk/fout is 8, FIG. 8 corresponds to a case of converting an output signal into an output signal of the sampling frequency one-eighth the high-speed operation clock frequency. In this case, ΔP is 2, and by switching the eight filter banks 2-0, 2-2, 2-4, 2-6, 2-8, 2-10, 2-12, and 2-14 sequentially, the output signal of the sampling frequency one-eighth the high-speed operation clock frequency is generated.

In the present embodiment, ΔP is used to determine the filter banks 2-0 to 2-(L-1) to be selected; however, other methods not using ΔP can be employed as long as selecting (switching) similar to that of the above method is performed based on the ratio between the high-speed operation clock frequency and the sampling frequency of the output signal.

When the filter banks 2-0 to 2-(L-1) and the switching unit 4 in the present embodiment are assumed as a single filtering unit, the control-signal generation unit 3 can be deemed to give this filtering unit an instruction of sets of the tap coefficients that are set for the filter banks 2-0 to 2-(L-1) selected as the output signal, when the filter banks 2-0 to 2-(L-1) are selected.

In the present embodiment, the filter banks 2-0 to 2-(L-1) to be selected are determined based on ΔP, which is the ratio between the high-speed operation clock frequency and the sampling frequency of the output signal; however, a method of determining the filter banks is not limited thereto and can be any method as long as it determines the filter banks 2-0 to 2-(L-1) based on the sampling frequency of the output signal.

As described above, in the present embodiment, the high-speed operation clock frequency is fixed, L filter banks 2-0 to 2-(L-1) corresponding to a maximum oversampling ratio L are provided, the phase generation unit 31 determines and gives an instruction for the filter banks 2-0 to 2-(L-1) to be selected, based on the ratio between the high-speed operation clock frequency and the sampling frequency of the output signal, and the switching unit 4 selects an output from the filter banks 2-0 to 2-(L-1) based on the instruction, and then outputs the selected one. Therefore, without combining a plurality of polyphase filters for upsampling and downsampling and with a simple configuration, sampling frequency conversion can be performed at any oversampling ratio not exceeding a maximum oversampling ratio while a high-speed operation clock frequency is fixed.

### Second Embodiment

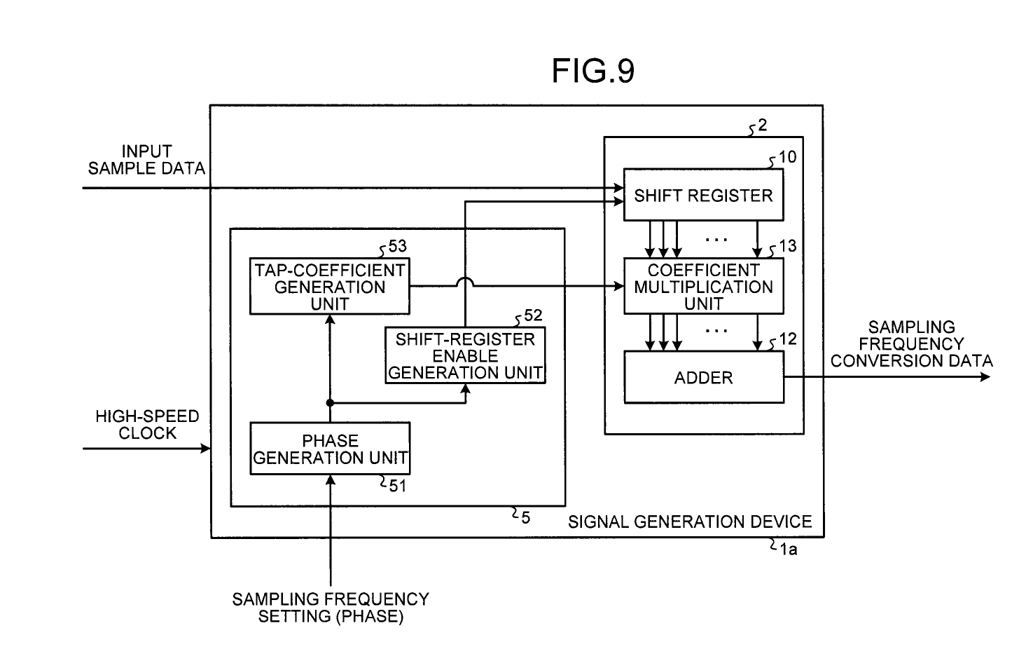

FIG. 9 is an example of a functional configuration of a signal generation device according to a second embodiment of the present invention. A signal generation device la according to the present embodiment is constituted by a filter bank 2 and a control-signal generation unit 5. The filter bank 2 has a configuration identical to that of the filter banks 2-0 to 2-(L-1) according to the first embodiment. While L filter banks are provided in the first embodiment, the signal device la according to the present embodiment has one filter bank 2.

Differences from the first embodiment are explained below. The control-signal generation unit 5 is constituted by a phase generation unit 51, a shift-register enable generation unit 52, and a tap-coefficient generation unit (filter control unit) 53. In the present embodiment, it is assumed that an operation is performed at the high-speed clock fclk corresponding to a maximum oversampling ratio. In the second embodiment, the maximum oversampling ratio L (resolution) is explained as 16.

Similarly to the phase generation unit 31 according to the first embodiment, the sampling frequency setting (phase) ΔP, which is determined based on the ratio between the high-speed clock frequency and the output sampling frequency, is input to the phase generation unit 51 of the control-signal generation unit 5. The method of calculating ΔP is the same as that in the first embodiment. When L is 16 and the ratio fclk/fout is 4, ΔP is 4. The phase generation unit 51 determines the output phase P(k) similarly to the phase generation unit 31 in the first embodiment, and then outputs to the shift-register enable generation unit 52 and the tap-coefficient generation unit 53.

An operation of the shift-register enable generation unit 52 is identical to that of the shift-register enable generation unit 32 according to the first embodiment. The tap-coefficient generation unit 53 holds the sets of the tap coefficients H₀ to H₁₂ shown in the first embodiment. The tap-coefficient generation unit 53 selects the set Hⱼ of the tap coefficients corresponding to j=P(k) based on the output phase P(k), and then outputs the selected set of the tap coefficients to the coefficient multiplication unit 13 of the filter bank 2. The coefficient multiplication unit 13 of the filter bank 2 sets the set of the tap coefficients output from the tap-coefficient generation unit 53 as the tap coefficients (C0 to C4). A signal having the filtering using the set of the tap coefficients Hⱼ performed thereon is output from the filter bank 2, as the output signal Ym obtained after the sampling frequency conversion. Operations of the present embodiment except for those explained above are identical to those of the first embodiment.

As described above, in the present embodiment, one filter bank 2 is provided, the tap-coefficient generation unit 53 holds the sets of the tap coefficients Ho to H₁₂, the set of the tap coefficients is selected based on P(k) calculated similarly to the first embodiment, and the coefficient multiplication unit 13 in the filter bank 2 sets the selected set of the tap coefficients. Therefore, the use of even one filter bank can achieve effects identical to those of the first embodiment, so that the configuration in the present embodiment can be simplified as compared to the first embodiment.

### Third Embodiment

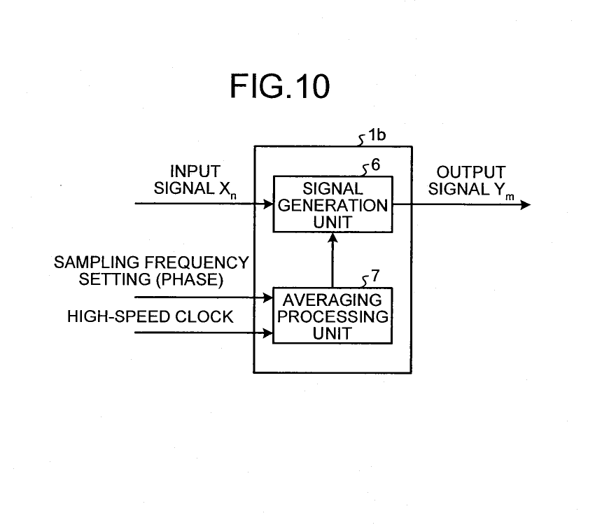

FIG. 10 is an example of a functional configuration of a signal generation device according to a third embodiment of the present invention. A signal generation device lb according to the present embodiment is constituted by a signal generation unit 6 and an averaging processing unit 7. The signal generation unit 6 has a configuration identical to that of the signal generation device 1 according to the first embodiment or that of the signal generation device la according to the second embodiment.

In the present embodiment, the sampling frequency setting (phase) ΔP is averaged and then input to the control-signal generation unit 3 according to the first embodiment or the control-signal generation unit 5 according to the second embodiment. While any configuration and method can be used for the configuration of the averaging processing unit 7 and for the averaging method thereof, in the present embodiment, an example of using an IIR (Infinite Impulse Response) filter is explained.

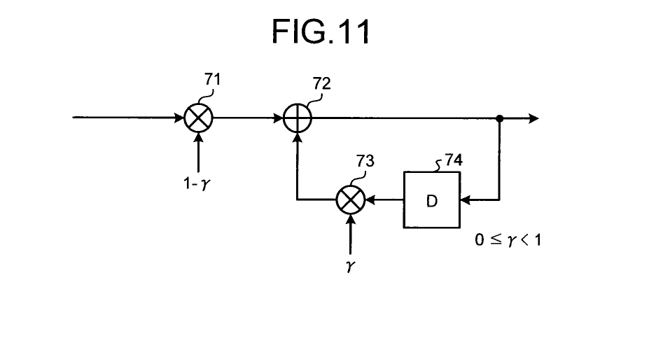

FIG. 11 is an example of the configuration of the averaging processing unit 7. As shown in FIG. 11, the averaging processing unit 7 is constituted by a multiplier 71, an adder 72, a multiplier 73, and a delay unit (D) 74. Note that γ(0≦γ<1) is a gain for setting smoothing of a filter. Because processing of the averaging processing unit 7 is identical to that of a general IIR filter, explanations thereof will be omitted. The averaging processing unit 7 is not limited to this configuration, and can be realized by other configurations such as that using primary and secondary loop filters. Operations of the present embodiment except for those explained above are identical to those of the first or second embodiment.

In the present embodiment, it is assumed that ΔP is input to the phase generation unit 51 and is averaged; however, when the sampling frequency of the output signal is input to the phase generation unit 51, the sampling frequency of the output signal is averaged.

As described above, in the present embodiment, by averaging the sampling frequency setting (phase) ΔP in advance, ΔP can be smoothly varied and the output sample signal can be also smoothly varied continuously. Therefore, the present embodiment can achieve effects identical to those in the first embodiment or the second embodiment, and when noise and the like are added on the sampling frequency setting (phase) or when the sampling frequency setting (phase) is changed at a midpoint, it is possible to smoothly vary the output signal.

### INDUSTRIAL APPLICABILITY

As described above, the signal generation device and the signal generation method according to the present invention are suitable for a signal generation device that generates a signal whose sampling frequency has been converted based on a sampled input signal, and are particularly suitable for a case where a converted sampling frequency of a signal is not fixed.

### REFERENCE SIGNS LIST

1, 1a, 1b signal generation device

2, 2-0 to 2-(L-1) filter bank

3, 5 control-signal generation unit

4 switching unit

6 signal generation unit

7 averaging processing unit

10 shift register

11-0 to 11-4 multiplier

12 adder

13 coefficient multiplication unit

31, 51 phase generation unit

32, 52 shift-register enable generation unit

33 filter control unit

53 tap-coefficient generation unit

71, 73 multiplier

72 adder

74 delay unit

1. A signal generation device comprising:
a filtering unit that performs sampling frequency conversion with respect to an input signal of a predetermined sampling frequency, and generates a signal obtained after the sampling frequency conversion as an output signal; and
a control unit that selects, based on a sampling-frequency setting value indicating a sampling frequency of the output signal, a combination of tap coefficients used by the filtering unit from a plurality of combinations of tap coefficients determined in advance, wherein
the filtering unit performs the sampling frequency conversion based on a result of selection by the control unit.

2. The signal generation device according to claim 1, wherein
the filtering unit includes
a plurality of filters for which different combinations of tap coefficients are respectively set, and
a switching unit that selects one of the filters based on an instruction of the control unit so as to designate the selected filter as the output signal, and
the control unit selects tap coefficients used by the filtering unit by determining the filter to be selected by the switching unit, based on the sampling-frequency setting value.

3. The signal generation device according to claim 1, wherein
the control unit holds the combinations of tap coefficients, and selects tap coefficients used by the filtering unit by selecting the combination of the tap coefficients, based on the sampling-frequency setting value,
the filtering unit includes one filter, and
the filter performs the sampling frequency conversion using the combination of the tap coefficients selected by the control unit.

4. The signal generation device according to claim 2, wherein the filter is an FIR filter.

5. The signal generation device according to claim 1, wherein the sampling-frequency setting value is a value calculated based on a ratio between an operation clock of the filtering unit and the sampling frequency of the output signal.

6. The signal generation device according to claim 5, wherein
the control unit includes
a phase generation unit that generates, based on the sampling-frequency setting value, a phase indicating a position of a combination of tap coefficients to be selected when the combinations of tap coefficients are arranged in a predetermined order, and
a filter control unit that selects tap coefficients used by the filtering unit based on the phase.

7. The signal generation device according to claim 6, wherein the phase generation unit generates the phase as a value such that a minimum value is 0 and a maximum value is a total number of the combinations of tap coefficients.

8. The signal generation device according to claim 7, wherein the phase generation unit generates the phase as a value obtained by rounding off or rounding down fractions.

9. The signal generation device according to claim 6, wherein the control unit further includes a shift-register enable generation unit that generates a shift-register enable signal for instructing an update timing of the input signal that is input to the filtering unit.

10. The signal generation device according to claim 9, wherein the shift-register enable generation unit generates the shift-register enable signal so as to instruct an update timing of the input signal when the phase becomes equal to or larger than a predetermined threshold.

11. The signal generation device according to claim 1, further comprising a averaging processing unit that averages the sampling-frequency setting value, wherein
the control unit designates a sampling-frequency setting value averaged by the averaging processing unit as the sampling-frequency setting value used to select tap coefficients to be used by the filtering unit.

12. The signal generation device according to claim 11, wherein the averaging processing unit is an BR filter.

13. The signal generation device according to claim 1, wherein the combinations of the tap coefficients are determined by applying polyphase decomposition to an impulse response of a predetermined filtering characteristic.

14. A signal generation method in a signal generation device including performing sampling frequency conversion with respect to an input signal of a predetermined sampling frequency, and generating a signal obtained after the sampling frequency conversion as an output signal, the method comprising:
a controlling step of selecting, based on a sampling-frequency setting value indicating a sampling frequency of the output signal, a combination of tap coefficients used by [[the]] a filtering unit from a plurality of combinations of the tap coefficients determined in advance; and
a sampling-frequency converting step of performing the sampling frequency conversion based on a result of selection at the controlling step.

15. The signal generation device according to claim 3, wherein the filter is an FIR filter.
